(19) United States
(12) Patent Application Publication
(10) Pub. No.: US 2012/0162919 A1
(43) Pub. Date: Jun. 28, 2012

(54) HEAT DISSIPATION DEVICE

(75) Inventor: TAI-WEI LIN, Tu-Cheng (TW)

(73) Assignee: HON HAI PRECISION INDUSTRY CO., LTD., Tu-Cheng (TW)

(21) Appl. No.: 12/981,419

(22) Filed: Dec. 29, 2010

(30) Foreign Application Priority Data
Dec. 24, 2010 (TW) 99145956

(51) Int. Cl. H05K 7/20

(52) U.S. Cl. 361/704

(57) ABSTRACT

A heat dissipation device for dissipating heat from an electronic component, includes two heat dissipating boards attached to two opposite lateral sides of the electronic component, respectively, and an elastic member securing the heat dissipating boards on the electronic component. Each of the heat dissipating boards includes a heat absorbing body, two heat dissipating arms extending upwardly from the heat absorbing body, and a plurality of fins extending outwardly from each of the heat dissipating arms.

### BACKGROUND

1. Technical Field

The disclosure relates to heat dissipation, and particularly to a heat dissipation device with enhanced heat dissipation performance.

2. Description of Related Art

Electronic components, such as memory banks comprise numerous circuits operating at high speeds and generating substantial heat. Under most circumstances, it is necessary to cool the memory banks to maintain safe operating conditions and assure that the memory banks function properly and reliably. In the past, various approaches have been used to cool electronic components. Typically, a fan is provided to the casing where the memory banks are disposed, which generates air-flow towards the memory banks. However, as the operating speed of electronic components increases markedly in the current environment, heat dissipation using only airflow may be insufficient for the amount of heat generated.

What is needed, therefore, is a heat dissipation device with enhanced heat dissipation performance.

### BRIEF DESCRIPTION OF THE DRAWINGS

FIG. 1 is an isometric, exploded view of a heat dissipation device in accordance with a first embodiment of the disclosure, with an electronic component mounted in the heat dissipation device.

FIG. 2 is an assembled view of FIG. 1.

FIG. 3 shows the heat dissipation device with the electronic component of FIG. 1 mounted in a working environment.

FIG. 4 is an isometric, exploded view of a heat dissipation device in accordance with a second embodiment of the disclosure, with an electronic component located below the heat dissipation device.

### DETAILED DESCRIPTION

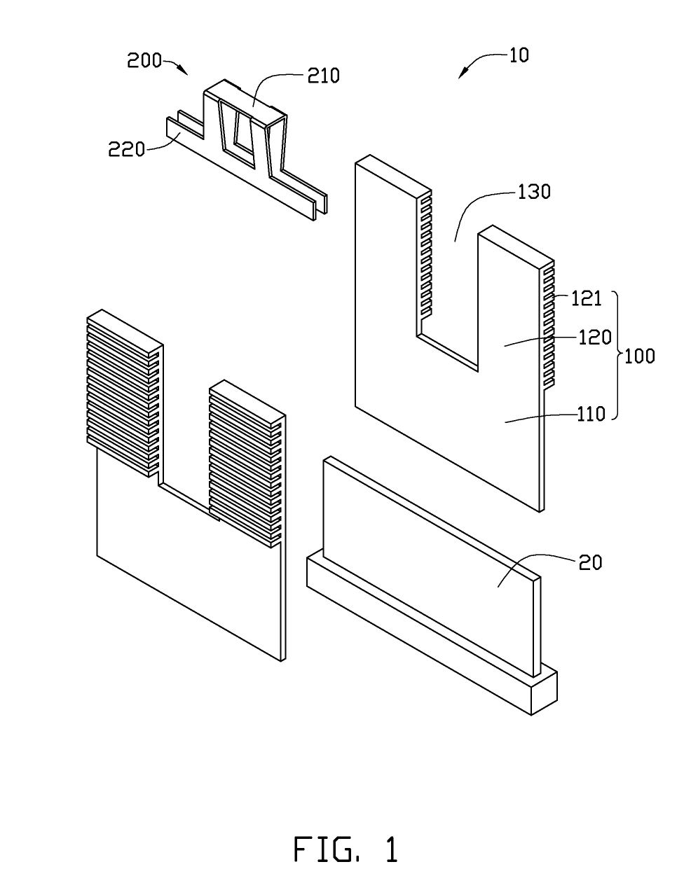

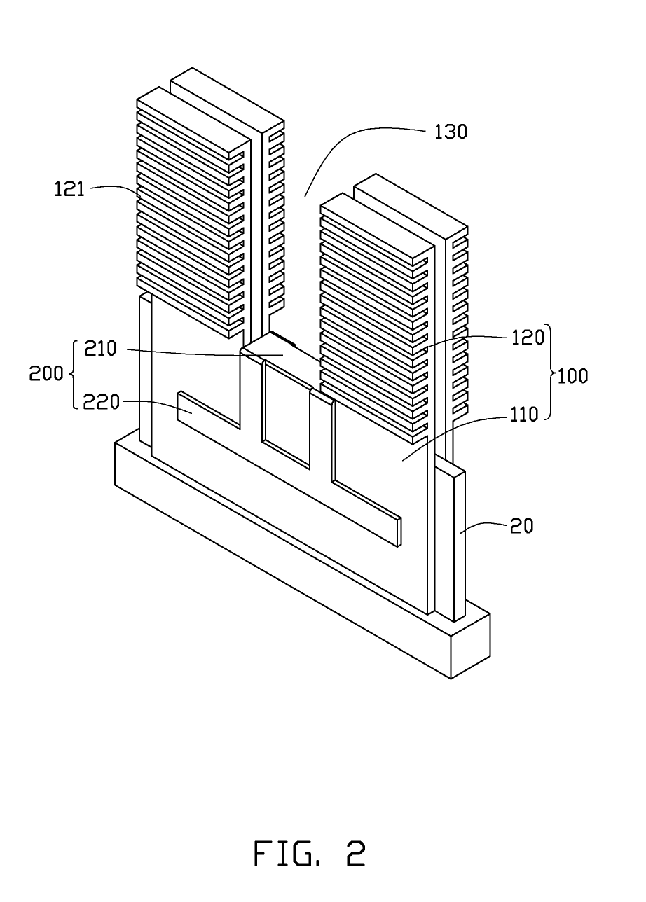

Referring to FIGS. 1-2, a heat dissipation device 10 in accordance with a first embodiment of the disclosure is disclosed. The heat dissipation device 10 dissipates heat from an electronic component 20 such as a memory bank. The heat dissipation device 10 comprises two heat dissipating boards 100 attached to the electronic component 20, and a fixing member 200 securing the two heat dissipating boards 100 on the electronic component 20.

The two heat dissipating boards 100 are attached to two opposite lateral sides of the electronic component 20, respectively, and aligned with each other. Each of the heat dissipating boards 100 is U-shaped, and made of a material with high heat conductivity, such as copper, aluminum or an alloy thereof. Each heat dissipating board 100 comprises a heat absorbing body 110, two heat dissipating arms 120 extending upwardly from a top side of the heat absorbing body 110, and a plurality of fins 121 extending outwardly from each of the heat dissipating arms 120. The heat absorbing body 110 is flat, rectangular and thin. The heat absorbing bodies 110 of the two heat dissipating boards 100 are attached to two opposite lateral sides of the electronic component 20, respectively; in other words, the electronic component 20 is sandwiched between the heat absorbing bodies 110 of the two heat dissipating boards 100. A thermal interface material (not shown) is applied between the two heat absorbing bodies 110 and the electronic component 20 to eliminate air interstices therebetween, thereby enhancing heat conduction from the electronic component 20 to the heat absorbing bodies 110. The two heat dissipating arms 120 are perpendicular to the heat absorbing body 110, and aligned with each other. The two heat dissipating arms 120 are spaced from each other, and a cutout 130 is defined between the two heat dissipating arms 120. The fins 121 are generally perpendicular to the heat dissipating arms 120, and are stacked horizontally. The fins 121 are spaced from, and parallel to each other. A passage (not labeled) is defined between every two neighboring fins 121 for the airflow flowing through.

The fixing member 200 is an elastic clip, and comprises a main board 210 and two fixing boards 220 extending downwardly from two opposite lateral sides of the main board 210, respectively. The main board 210 is disposed in the two cutouts 130 of the two heat dissipating boards 100, and on top faces of the two heat absorbing bodies 110 of the two heat dissipating boards 100. The two fixing boards are extended inclinedly towards each other. The two heat absorbing bodies 110 and the electronic component 20 are together sandwiched between the two fixing boards 220 of the fixing member 200.

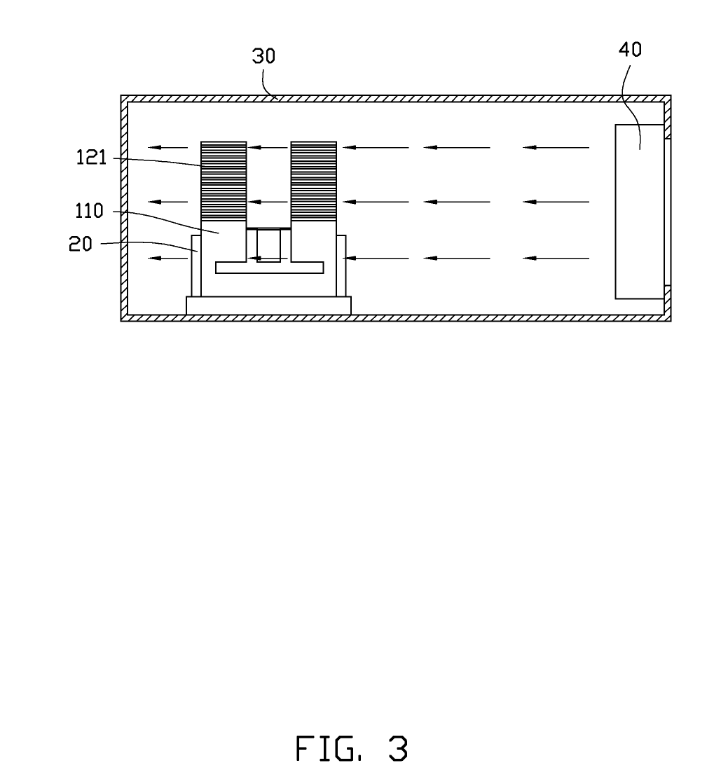

Referring to FIG. 3 also, in use, the electronic component 20 is disposed in a casing 30 with a fan 40 mounted in the casing 30 and providing airflow towards the electronic component 20. The heat dissipation device 10 is assembled on the electronic component 20. The airflow generated by the fan 40 flows through the fins 121 of the two heat dissipating boards 100 of the heat dissipation device 10. The heat generated by the electronic component 20 is conducted to the heat absorbing bodies 110 and then reaches the heat dissipating arms 120, and finally dissipated into ambient through the fins 121.

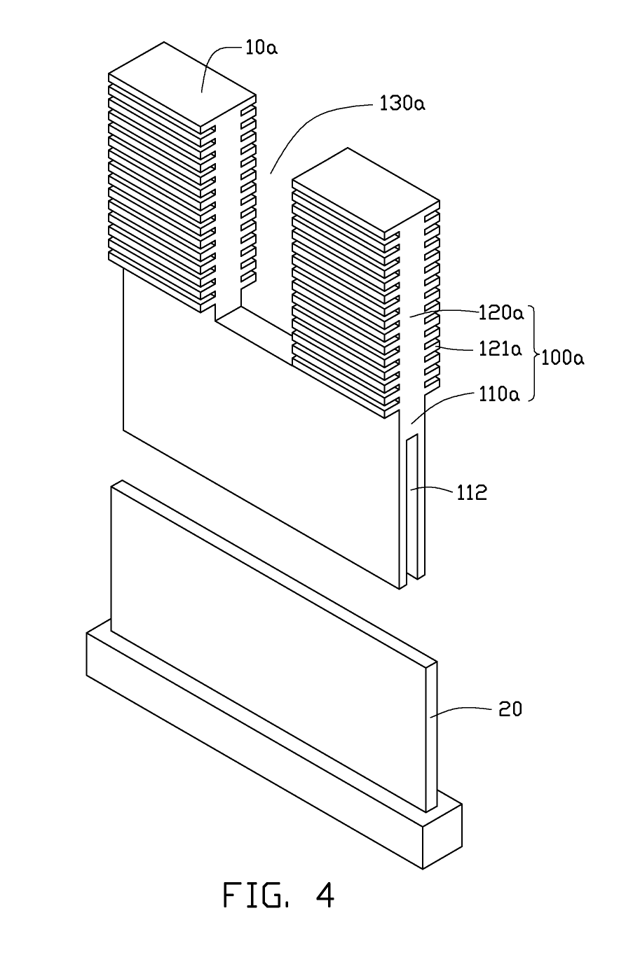

FIG. 4 shows a heat dissipation device 10a according to an alternative embodiment, differing from the previous embodiment. In this embodiment, the heat dissipation device 10a comprises a heat absorbing portion 110a disposed on the electronic component 20, two heat dissipating arms 120a extending upwardly from a top side of the heat absorbing portion 110a, and a plurality of fins 121a extending outwardly from each of the heat dissipating arms 120a. The heat dissipation device 10a is integrally made by a single piece of metal of other heat-conductive materials. A bottom portion of the heat absorbing portion 110a defines an elongated receiving groove 112. The electronic component 20 is fitly received in the receiving groove 112 of the heat absorbing portion 110a. A thermal interface material (not shown) is applied between the heat absorbing portion 110a and the electronic component 20 to eliminate air interstices therebetween, thereby enhancing heat conduction from the electronic component 20 to the heat absorbing portion 110a. The two heat dissipating arms 120a are perpendicular to the heat absorbing portion 110a, and aligned with each other. The two heat dissipating arms 120a are spaced from each other, and a cutout 130a is defined between the two heat dissipating arms 120a. The fins 121a are generally perpendicular to the heat dissipating arms 120a, and are stacked horizontally. The fins 121a are spaced from, and parallel to each other. A passage (not labeled) is defined between every two neighboring fins 121a for the airflow flowing through. In use, the heat generated by the electronic component 20 is conducted to the heat absorbing portion 110a and then reaches the heat dissipating arms 120a, and finally dissipated into ambient through the fins 121a.

It is to be understood, however, that even though numerous characteristics and advantages of certain embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A heat dissipation device for dissipating heat from an electronic component, the heat dissipation device comprising:
a heat sink comprising two heat dissipating boards attached to two opposite lateral sides of the electronic component, respectively; and
an elastic member securing the heat dissipating boards on the electronic component;
wherein each of the heat dissipating boards comprises a heat absorbing body, two heat dissipating arms extending upwardly from the heat absorbing body, and a plurality of fins extending outwardly from each of the heat dissipating arms.

2. The heat dissipation device of claim 1, wherein the electronic component is sandwiched between the two heat dissipating boards.

3. The heat dissipation device of claim 1, wherein the two heat dissipating arms are perpendicular to the heat absorbing body, and aligned with each other.

4. The heat dissipation device of claim 1, wherein the two heat dissipating arms are spaced from each other, and a cutout is defined between the two heat dissipating arms.

5. The heat dissipation device of claim 1, wherein the fins are spaced from, and parallel to each other.

6. The heat dissipation device of claim 5, wherein a passage is defined between every two neighboring fins.

7. The heat dissipation device of claim 1, wherein the elastic member comprises a main board and two fixing boards extending downwardly from two opposite lateral sides of the main board, respectively.

8. The heat dissipation device of claim 7, wherein the two heat absorbing bodies and the electronic component are together sandwiched between the two fixing boards of the fixing member.

9. The heat dissipation device of claim 1 further comprises a thermal interface material applied between the two heat absorbing bodies and the electronic component.

10. A heat dissipation device for dissipating heat from an electronic component, the heat dissipation device comprising:
a heat sink comprising a heat absorbing portion disposed on the electronic component, respectively, two heat dissipating arms extending upwardly from the heat absorbing portion, and a plurality of fins extending outwardly from each of the heat dissipating arms;
wherein the heat absorbing portion defines a receiving groove, and the electronic component is received in the receiving groove.

11. The heat dissipation device of claim 10, wherein the two heat dissipating arms are perpendicular to the heat absorbing portion, and aligned with each other.

12. The heat dissipation device of claim 10, wherein the two heat dissipating arms are spaced from each other, and a cutout is defined between the two heat dissipating arms.

13. The heat dissipation device of claim 10, wherein the fins are spaced from, and parallel to each other.

14. The heat dissipation device of claim 13, wherein a passage is defined between every two neighboring fins.

15. The heat dissipation device of claim 10 further comprises a thermal interface material applied between the heat absorbing portion and the electronic component.

16. The heat dissipation device of claim 10 being made by a single piece of heat conductive material.
